(19) United States
(12) Patent Application Publication
(10) Pub. No.: US 2026/0227337 A1
(43) Pub. Date: Aug. 6, 2026

(54) METHODS AND SYSTEMS FOR PREDICTING SUBSTRATE PROCESS EMISSIONS CHEMISTRY

(71) Applicant: Applied Materials, Inc., Santa Clara, CA (US)

(72) Inventors: Benjamin Jay Gross, Castro Valley, CA (US); Joseph Anthony Van Gompel, Austin, TX (US); Naga Varma Ravikumar Nadimpalli, Bangalore (IN); Anika Singhania, Fremont, CA (US); Elizabeth Kathryn Neville Reyes, Santa Clara, CA (US)

(21) Appl. No.: 19/046,265

(22) Filed: Feb. 5, 2025

(51) Int. Cl. G01N 21/76; H01L 21/66; H01L 21/67

(52) U.S. Cl. CPC G01N 21/766; H10P 72/0604; H10P 74/277; G01N 2201/1293; G01N 2201/1296

(57) ABSTRACT

Methods and systems for predicting substrate process emissions chemistry are provided. A process recipe for a process to be performed using one or more manufacturing equipment is provided as an input to an artificial intelligence (AI) model. The AI model is trained to predict emissions characterization data for a respective process based on a given process recipe. Output(s) of the AI model is obtained, where the output(s) indicate emissions characterization data associated with the process. A determination is made of whether the emissions characterization data associated with the process satisfies one or more emission criteria. Upon a determination that the emissions characterization data associated with the process satisfies the one or more emission criteria, one or more operations of the process are performed using the one or more manufacturing equipment in accordance with the process recipe.

### TECHNICAL FIELD

Embodiments of the present disclosure relate, in general, to manufacturing systems and more particularly to methods and systems for predicting substrate process emissions chemistry.

### BACKGROUND

Semiconductor manufacturing involves processes such as plasma etching, chemical vapor deposition (CVD), chamber cleaning, etc., which often use high global warming potential gases, including perfluorocarbons (PFCs), sulfur hexafluoride (SF₆), etc. Global and industry standards offer strict standards for abatement of such gases, for protection of workers and the environment. Proper emissions monitoring helps ensure compliance with such standards, protect worker health, and support sustainable manufacturing practices.

### SUMMARY

Some of the embodiments described cover a system and method calibrating on-tool digital twin models. The method includes identifying a process recipe for one or more operations of a process to be performed using one or more manufacturing equipment. The method further includes providing the process recipe as an input to an artificial intelligence (AI) model trained to predict emissions characterization data for operations of a respective process based on a given process recipe. The method further includes obtaining one or more outputs of the AI model indicating emissions characterization data associated with the one or more operations of the process. The emissions characterization data includes one or more of an indication of one or more emission gases produced based on the one or more operations of the process in accordance with the process recipe, or an indication of an amount of each of the one or more emission gases. The method further includes determining whether the emissions characterization data associated with the one or more operations satisfies one or more emission criteria. The method further includes, responsive to determining that the emissions characterization data associated with the one or more operations satisfies the one or more emission criteria, performing the one or more operations of the process using the one or more manufacturing equipment in accordance with the process recipe.

In some implementations, the method further includes, responsive to determining that the emissions characterization data for the one or more operations of the process does not satisfy the one or more emission criteria, updating one or more settings of the process recipe. The method further includes performing the one or more operations of the process using the one or more manufacturing equipment in accordance with the updated one or more settings of the process recipe.

In some implementations, the method further includes providing the updated one or more settings of the process recipe as an additional input to the AI model. The method further includes obtaining one or more additional outputs of the AI model including updated emissions characterization data for the process. The updated emissions characterization data includes one or more of an indication of the one or more emission gases produced by the process performed in accordance with the updated one or more settings of the process recipe, or an indication of an updated amount of the one or more emission gases. The process is performed using the one or more manufacturing equipment in accordance with the updated one or more settings of the process recipe responsive to a determination that the updated emissions characterization data for the process satisfies the one or more emission criteria.

In some implementations, the AI model is further trained to predict one or more settings of the respective process recipe that have a higher degree of impact on the predicted emissions characterization data than other settings of the respective process recipe. Updating the one or more settings of the process recipe includes determining, based on the one or more outputs of the AI model, the one or more settings of the process recipe that have the higher degree of impact on the emissions characterization data associated with the process. The method further includes determining updated values for each of determined one or more settings.

In some implementations, the one or more manufacturing equipment includes at least one of a processing chamber that performs the process, or an abatement system that performs one or more abatement operations on one or more gases of an outlet of the processing chamber.

In some implementations, determining whether the emissions characterization data associated with the process satisfies the one or more emission criteria includes at least one of determining whether the indicated one or more emission gases include a restricted emission gas, or determining whether an amount of the one or more emission gases falls below a threshold amount.

In some implementations, the process includes at least one of an etching process, a deposition process, a polishing process, a lithographic process or a cleaning process.

In some implementations, the method further includes transmitting the emissions characterization data associated with the one or more operations of the process to a client device for presentation to a user via a user interface of the client device.

In some implementations, the process recipe is for one or more operations of a substrate process to be performed using a process chamber. The method further includes identifying an additional process recipe of an abatement process to be performed using an abatement system subsequent to performance of one or more operations of the process using the process chamber. The method further includes providing the identified additional process recipe and the emissions characterization data associated with the one or more operations of the process as an input to an additional AI model trained to predict emissions characterization data for operations of a respective abatement process following a respective substrate. The method further includes obtaining one or more outputs of the additional AI model that includes additional emissions characterization data associated with the abatement process performed subsequent to the one or more operations of the process using the process chamber. The one or more operations of the process are performed in accordance with the process recipe responsive to a further determination that the additional emissions characterization data satisfies the one or more emissions criteria.

In some implementations, a system includes a memory and a set of one or more processing devices coupled to the memory. The set of one or more processing devices is to generate training data for training a machine learning model to predict emissions characterization data for a respective process recipe. To generate the training data, the set of one or more processing devices is to generate a training input including a process recipe associated with one or more operations of a historical process performed using one or more manufacturing equipment. The set of one or more processing devices is further to generate a target output for the training input. The target output includes historical emissions characterization data collected for the one or more operations of the historical process. The historical emissions characterization data includes one or more of an indication of one or more emissions gases produced based on the one or more operations of the historical process in accordance with the process recipe, or an indication of an amount of each of the one or more emission gases. The set of one or more processing devices is further to provide the training data to train the machine learning model on (i) a set of training inputs including the training input and (ii) a set of target outputs including the target output.

In some implementations, the set of one or more processing devices is further to identify historical spectral data associated with the one or more emissions gases produced based on the one or more operations of the historical process. The set of one or more processing devices is further to determine, based on the historical spectral data, one or more of a composition of the one or more emissions gases and a concentration of the one or more emissions gases.

In some implementations, the set of one or more processing devices is to perform at least one of determining the one or more emissions gases produced based on the one or more operations of the historical process based on the determined composition of the one or more emissions gases, or determining the amount of each of the one or more emissions gases based on the determined concentration of the one or more emissions gases.

In some implementations, the one or more manufacturing equipment includes at least one of a processing chamber that performs the historical process, or an abatement system that performs one or more historical abatement operations on one or more gases of an outlet of the processing chamber.

In some implementations, the historical process includes at least one of a historical etching process, a historical deposition process, a historical polishing process, a historical lithographic process, a historical cleaning process, or a historical abatement process.

In some implementations, the target output for the training input further includes an indication of one or more settings of the process recipe that have a higher degree of impact on the historical emissions characterization data than other settings of the process recipe.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts an illustrative system architecture, according to aspects of the present disclosure.

FIG. 2 is a block diagram of an example process emissions engine, according to aspects of the present disclosure.

FIG. 3 is block diagram depicting an example method for training an artificial intelligence model, according to aspects of the present disclosure.

FIG. 4 is a flow chart of an example method for predicting a substrate process emissions chemistry, according to aspects of the present disclosure.

FIG. 5 is a flow chart of another example method for predicting a substrate process emissions chemistry, according to aspects of the present disclosure.

FIG. 6 depicts a block diagram of an illustrative computer system operating in accordance with one or more aspects of the present disclosure.

### DETAILED DESCRIPTION OF EMBODIMENTS

Implementations described herein provide methods and systems for predicting a substrate process emissions chemistry. Semiconductor manufacturing relies on multiple complex processes that involve a variety of chemical reactions, some of which produce greenhouse gas emissions (e.g., including perfluorocarbons (PFCs), sulfur hexafluoride (SF₆), among other gases). As the semiconductor industry advances towards smaller, more efficient devices, the use of such chemical reactions increases, leading to a greater environmental impact. To align with global and industry sustainability goals, semiconductor manufacturers are focusing on accurately characterizing and quantifying these emissions, which can inform the manufacturers on the degree to which their systems contribute to overall greenhouse gas emissions and/or how to reduce their overall greenhouse gas emissions.

Conventional emission characterization techniques rely on aggregated data collected for a sampling of process chemistries. For example, some entities (e.g., government entities, industry groups, etc.) collect emissions data for a sampling of process chemistries and determine, for a respective process chemistry, aggregate emissions data representing emissions chemistries and/or concentrations for the process chemistry. Such entities publish data mapping the aggregate emissions data to reactant data associated with the process chemistries (e.g., a type and amount of reactant provided as input to a process chamber, etc.). Some semiconductor manufacturing systems may use such published data to attempt to characterize and/or quantify their own process emissions. For example, for a process that involves process chemistries including a particular reactant (or set of reactants), the system may identify, based on the published data, aggregate emission data corresponding to the reactant(s) and may develop and/or perform such process treating the aggregate emission data as representing the emissions of the process.

As indicated above, the conventional aggregate emissions data is obtained for only a sampling of process chemistries for a finite set of processes, and does not account for continuous improvements in manufacturing equipment, new or updated process chemistries and/or process recipes, or improved abatement technologies that may be implemented at a respective manufacturing system. Accordingly, such aggregate emissions data may not accurately reflect the emissions of a respective manufacturing system, and the actual emissions for the respective manufacturing system may be significantly different from what is indicated by the aggregate emissions data. For example, an amount of a particular emissions gas for a process may be much higher or much lower at a respective manufacturing system than indicated by the aggregate emissions data (e.g., due to improved equipment used at the manufacturing system, an updated or modified process chemistry and/or process recipe for the process, etc.). In view of the above, conventional emission characterization and/or quantification techniques do not enable manufacturing systems to accurately determine the emissions of processes performed at such manufacturing systems, which can lead to an (e.g., unintentional) increase of greenhouse gas emissions from the manufacturing systems and/or overcorrecting of the processes (e.g., to attempt to reduce the greenhouse gas emissions).

Aspects of the present disclosure address the above noted and other deficiencies by providing methods and systems for artificial intelligence (AI)-based techniques for characterizing and/or quantifying emissions of processes at a manufacturing system. An AI model (e.g., a machine learning model) can be trained to predict emissions characterization data associated with one or more operations of a process to be performed using one or more manufacturing equipment of a manufacturing system. The emissions characterization data can include an indication of one or more emissions gases produced based on the one or more operations of the process in accordance with the process recipe and/or an indication of an amount of each of the one or more emissions gases. In some instances, the AI model can be trained based on training data that includes a set of training inputs and a set of target outputs. A training input can include a process recipe associated with one or more operations of a historical process performed using one or more manufacturing equipment (e.g., of the manufacturing system or of another manufacturing system). A target output of the training input can include historical emissions characterization data for the one or more operations of the historical process. In some instances, the system can obtain the historical emissions characterization data by identifying historical spectral data associated with the one or more emissions gases produced by the operation(s) of the historical process. The historical spectral data may be collected using a spectroscopy component configured to analyze a gas stream of an outlet of the manufacturing equipment (e.g., at an outlet of a processing chamber, at an outlet of an abatement system, etc.). The spectroscopy component can include any type of spectroscopy equipment that is capable of analyzing a composition of a gas stream.

Upon training the AI model, the AI model can be applied to process recipe data for a future process to be performed at the manufacturing system. For example, the system can identify a process recipe for one or more operations of a process to be performed using one or more manufacturing equipment of the manufacturing system and can provide the process recipe as an input to the trained AI model. The system can obtain one or more outputs of the AI model, which include emissions characterization data associated with the one or more operations of the process. The emissions characterization data includes an indication of one or more gas emissions produced based on the one or more operations of the process in accordance with the process recipe and/or an indication of an amount of each of the emission gases. The system can determine whether the emissions characterization data satisfies one or more emission criteria and, if so, can perform the one or more operations of the process using the manufacturing equipment in accordance with the process recipe. In some instances, the system can determine whether the emissions characterization data satisfies the one or more emission criteria by determining whether the indicated one or more emission gases include a restricted emission gas (e.g., an emission gas that cannot or should not be emitted in view of regulations and/or public policy) and/or determining whether the amount of the one or more emissions gases falls below a threshold.

Upon determining that the emissions characterization data for the one or more operations of the process does not satisfy the one or more emission criteria, the system can update one or more settings of the process recipe and provide the updated one or more settings as an additional input to the AI model. The system can obtain one or more additional outputs of the AI model, which include additional characterization data for the operation(s) of the process in view of the updated one or more settings. Upon determining that the updated emissions characterization data satisfies the emission criteria, the system can perform the one or more operations of the process in accordance with the updated one or more settings. In some instances, the AI model can be further trained to predict one or more settings of a respective process recipe that have a higher degree of impact on the predicted emissions characterization data than other settings of the process recipe. The system can identify the one or more settings to update based on one or more outputs of the AI model that indicate such settings as having a higher degree of impact on the emissions characterization data.

Aspects of the present disclosure address deficiencies of the conventional technology by providing AI-based techniques for predicting process emissions chemistry based on substrate process recipe data for the process. As described herein, an AI model can be trained to predict emissions characterization data associated with operations of a process performed using manufacturing equipment. The AI model can be retrained or otherwise updated in accordance with updates to manufacturing equipment and/or substrate processes performed using the manufacturing equipment. Accordingly, semiconductor manufacturing systems can access data that more accurately reflects emissions characteristics for the updated equipment and/or the updated processes and take appropriate actions to mitigate the emissions (e.g., in accordance with global and industry emissions standards). For example, based on the emissions characteristics data obtained based on one or more outputs of the AI model, a manufacturing system can identify settings of a process recipe that impact emissions of a process more than other settings of the process recipe, and can update such identified settings to mitigate process emissions (e.g., to meet or fall below emissions standards). By mitigating emissions of a substrate process at a processing chamber, fewer resources (e.g., manufacturing resources, computing resources, etc.) are consumed by abatement systems performing abatement processes for such emissions, which improves an overall efficiency and throughput of the system. By further mitigating emissions of the abatement process performed subsequent to the substrate process, there are fewer overall emissions for a substrate process, which decreases an overall environmental impact and improves a working environment of the system.

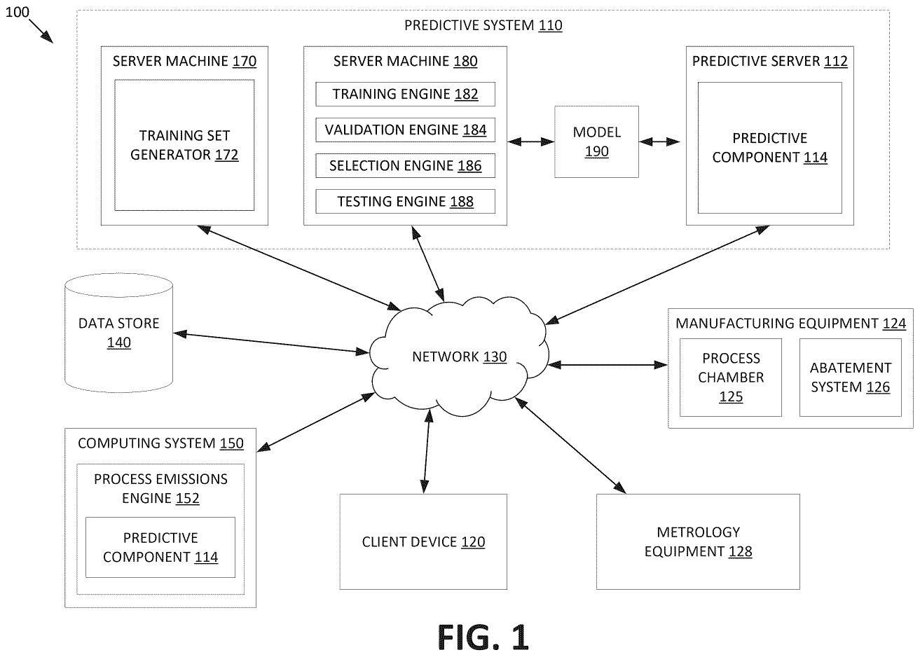

FIG. 1 depicts an illustrative system architecture 100, according to aspects of the present disclosure. System architecture 100 can include a client device 120, manufacturing equipment 124, metrology equipment 128, a predictive server 112 (e.g., to generate predictive data, to provide model adaptation, to use a knowledge base, etc.), and/or a data store 140. The predictive server 112 can be part of a predictive system 110. The predictive system 110 can further include server machines 170 and 180. In some embodiments, system architecture 100 can be included as part of or otherwise connected to a manufacturing system for processing substrates.

Manufacturing equipment 124 can produce products, such as electronic devices, following a recipe or performing runs over a period of time. Manufacturing equipment 124 can include a process chamber 125. Manufacturing equipment 124 can perform a process for a substrate (e.g., a wafer, etc.) at the process chamber 125. Examples of substrate processes include a deposition process to deposit a film on a surface of the substrate, an etch process to form a pattern on the surface of the substrate, a polishing process to polish a material on the surface of the substrate, etc. Manufacturing equipment 124 can perform each process according to a process recipe. A process recipe defines a particular set of operations to be performed for the substrate during the process and can include one or more settings associated with each operation. For example, a deposition process recipe can include a temperature setting for the process chamber, a pressure setting for the process chamber, a flow rate setting for a precursor for a material included in the film deposited on the substrate surface, etc. Substrates that are processed according to a process recipe (e.g., for manufacturing a portion of an electronic device, etc.) are referred to herein as production substrates.

Manufacturing equipment 124 can include one or more sensors configured to capture data for a substrate being processed at the manufacturing system. In some embodiments, the manufacturing equipment 124 and the sensors can be part of a sensor system that includes a sensor server (e.g., field service server (FSS) at a manufacturing facility) and sensor identifier reader (e.g., front opening unified pod (FOUP) radio frequency identification (RFID) reader for sensor system). Sensor data may include a value of one or more of temperature (e.g., heater temperature), spacing (SP), pressure, high frequency radio frequency (HFRF), RF bias, voltage of electrostatic chuck (ESC), electrical current, flow, power, voltage, etc. Sensor data may be associated with or indicative of manufacturing parameters such as hardware parameters, such as settings or components (e.g., size, type, etc.) of the manufacturing equipment 124, or process parameters of the manufacturing equipment 124. The sensor data can be provided while the manufacturing equipment 124 is performing manufacturing processes (e.g., equipment readings when processing products). The sensor data 142 can be different for each substrate. In some embodiments, sensor data can include trace data collected during performance of one or more processes (e.g., substrate processes, maintenance processes, etc.) at manufacturing equipment 124. Trace data refers to data that indicates how components in a process chamber are operating and/or a state of an environment within a process chamber before, during, or after performance of an operation. Further details regarding sensor data are provided herein.

Metrology equipment 128 provides metrology data associated with substrates (e.g., production substrates, seasoning substrates, etc.) processed by manufacturing equipment 124. The metrology data can include a value of one or more of film property data (e.g., wafer spatial film properties), dimensions (e.g., thickness, height, etc.), dielectric constant, dopant concentration, density, defects, etc. In some embodiments, the metrology data can further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data can be of a finished or semi-finished product. The metrology data can be different for each substrate. Metrology equipment 128 can be configured to generate metrology data associated with a substrate before or after a substrate process and/or a maintenance process. In some embodiments, metrology equipment 128 can be part of a metrology system that includes a metrology server (e.g., a metrology database, metrology folders, etc.) and metrology identifier reader (e.g., FOUP RFID reader for metrology system).

Metrology equipment 128 can be integrated with a station of the process tool of manufacturing equipment 124. In some embodiments, metrology equipment 128 can be coupled to or be a part of a station of the process tool that is maintained under a vacuum environment (e.g., a process chamber, a transfer chamber, etc.). Such metrology equipment 128 is referred to as integrated metrology equipment. Accordingly, the substrate can be measured by the integrated metrology equipment while the substrate is in the vacuum environment. For example, after a process (e.g., an etch process, a deposition process, etc.) is performed for the substrate, the metrology data for the substrate can be generated by the integrated metrology equipment without the processed substrate being removed from the vacuum environment. In other or similar embodiments, metrology equipment 128 can be coupled to or be a part of the process tool station that is not maintained under a vacuum environment (e.g., a factory interface module, etc.). Such metrology equipment is referred to as inline metrology equipment. Accordingly, the substrate is measured by the inline metrology equipment outside of the vacuum environment.

In additional or alternative embodiments, metrology equipment 128 can include metrology measurement devices that are separate (i.e., external) from manufacturing equipment 124. For example, metrology equipment 128 can be standalone equipment that is not coupled to any station of manufacturing equipment 124. For a measurement to be obtained for a substrate using external metrology equipment, a user of a manufacturing system (e.g., an engineer, an operator) can cause a substrate processed at manufacturing equipment 124 to be removed from manufacturing equipment 124 and transferred to metrology equipment 128 for measurement. In some embodiments, metrology equipment 128 can transfer metrology data generated for the substrate to the client device 120 coupled to metrology equipment 128 via network 130 (e.g., for presentation to a manufacturing user, such as an operator or an engineer). In other or similar embodiments, the manufacturing system user can obtain metrology data for the substrate from metrology equipment 128 and can provide the metrology data to computer system architecture via a graphical user interface (GUI) of client device 120.

The client device 120 my include a computing device such as personal computers (PCs), laptops, mobile phones, smart phones, tablet computers, netbook computers, network connected televisions (“smart TVs”), network-connected media players (e.g., Blu-ray player), a set-top box, over-the-top (OTT) streaming devices, operator boxes, etc. In some embodiments, the metrology data may be received from the client device 120. In some embodiments, client device 120 displays a graphical user interface (GUI), where the GUI enables the user to provide, as input, metrology measurement values for substrates processed at the manufacturing system. In other or similar embodiments, client device 120 can display another GUI that enables user to provide, as input, an indication of a type of substrate to be processed at the manufacturing system, a type of process to be performed for the substrate, and/or a type of equipment at the manufacturing system. In yet other or similar embodiments, client device 120 can display another GUI that that presents sensor data collected by the sensors before, during, or after performance of a process (e.g., a substrate process, a maintenance process, etc.). It should be noted that one or more GUIs of client device 120 can provide and/or receive any data described herein.

Data store 140 can be a memory (e.g., random access memory), a drive (e.g., a hard drive, a flash drive), a database system, or another type of component or device capable of storing data. Data store 140 can include multiple storage components (e.g., multiple drives or multiple databases) that can span multiple computing devices (e.g., multiple server computers). The data store 140 can store data associated with processing a substrate at manufacturing equipment 124. For example, data store 140 can store data collected by the sensors at manufacturing equipment 124 before, during, or after a substrate process (referred to as process data). Process data can refer to historical process data (e.g., process data generated for a previous substrate processed at the manufacturing system) and/or current process data (e.g., process data generated for a current substrate processed at the manufacturing system). Current process data can be data for which predictive data is generated. In some embodiments, data store can store metrology data including historical metrology data (e.g., metrology measurement values for a prior substrate processed at the manufacturing system). The data store 140 can also store contextual data associated with one or more substrates processed at the manufacturing system. Contextual data can include a recipe name, recipe operation number, preventive maintenance indicator, operator, etc. In some embodiments, contextual data can also include an indication of a difference between two or more process recipes or process operations.

In some embodiments, data store 140 can be configured to store data that is not accessible to a user of the manufacturing system. For example, process data, spectral data, non-spectral data, and/or positional data obtained for a substrate being processed at the manufacturing system may not be accessible to a user of the manufacturing system. In some embodiments, all data stored at data store 140 is inaccessible by a user (e.g., an operator) of the manufacturing system. In other or similar embodiments, a portion of data stored at data store 140 is inaccessible by the user while another portion of data stored at data store 140 is accessible by the user. In some embodiments, one or more portions of data stored at data store 140 are encrypted using an encryption mechanism that is unknown to the user (e.g., data is encrypted using a private encryption key). In other or similar embodiments, data store 140 includes multiple data stores where data that is inaccessible to the user is stored in one or more first data stores and data that is accessible to the user is stored in one or more second data stores.

As described above, manufacturing equipment 124 can include a process chamber 125 that performs a process for a substrate. In some instances, emissions gases can be generated or can otherwise result from the substrate process. An emission gas refers to a gaseous substance that is formed as a byproduct of a reaction involving a materials of the substrate process. In some embodiments, emission gases (also referred to herein as emissions) of a substrate process can include gases that are recognized (e.g., by the semiconductor industry, by government agencies, by scientific experts, etc.) as negatively impacting environmental conditions of a manufacturing system and/or an overall environment. Such gases can include greenhouse gases which are recognized to contribute to global warming and climate change (e.g., carbon dioxide (CO₂), methane (CH₄), perfluorocarbons (PFCs), etc.). Emissions gases can include non-greenhouse gases, in other or similar embodiments.

In some embodiments, manufacturing equipment 124 can include an abatement system 126 that performs one or more abatement operations to treat and/or reduce emissions of a process chamber 125. An abatement operation can include a neutralization operation (e.g., to neutralize emission gases through chemical reactions), a particulate removal operation (e.g., to capture and separate fine particles from a waste stream), a thermal destruction operation (e.g., to burn, oxidize, or otherwise destroy emission gases into less harmful substances using high heat), a catalytic conversion operation (e.g., to lower the activation energy associated with breaking down emission gases), a recycling and recovery operation (e.g., to capture and recycle gases to be reused for a future substrate process), and so forth. In some embodiments, the abatement operation can include a plasma-based abatement operation, which reduces or eliminates emissions based on plasma technology. In some instances, abatement system 126 may be unable to treat and/or destroy all emissions (e.g., due to chemical or physical limitations of the abatement operations). Accordingly, some emissions may be present after performance of the abatement operation(s) (e.g., emissions of the substrate process and/or new emissions from the abatement operation(s).

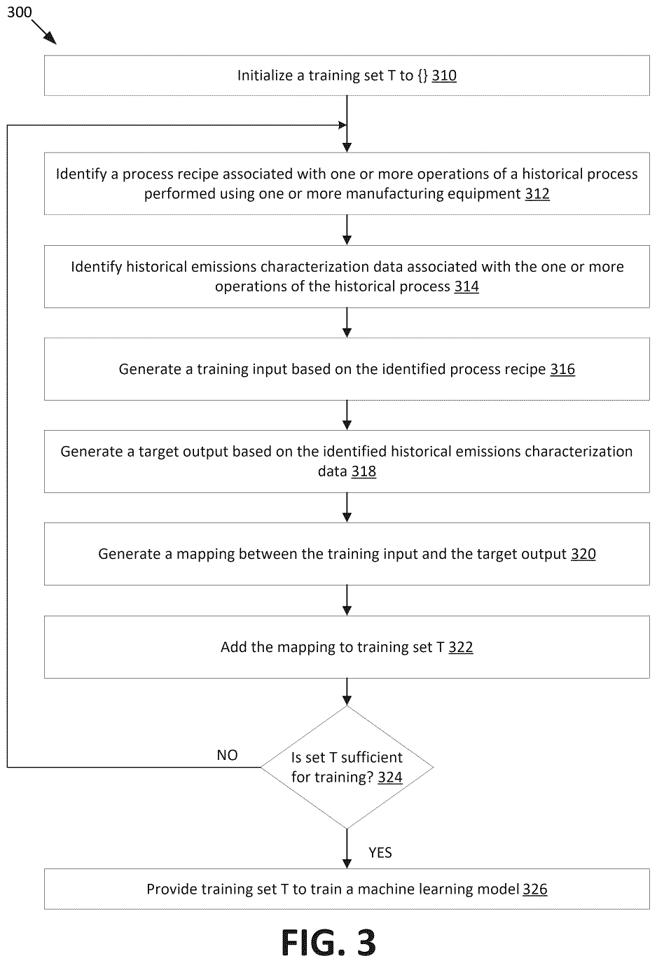

Computing system 150 can include a process emissions engine 152 that can obtain emissions characterizations data associated with emissions of process chamber 125 and/or of abatement system 126 and, in some embodiments, update a process recipe for a substrate process to mitigate emissions for the substrate process. In some embodiments, process emissions engine 152 can include or have access to a predictive component 114 (e.g., of predictive system 110) which provides process recipe data for a substrate process as an input to an artificial intelligence (AI) model 190 trained to predict emissions characterization data for operations of a process (e.g., a substrate process, an abatement process, etc.) based on a given process recipe. Emissions characterization data can include an indication of one or more emission gases produced by the process and/or an indication of an amount (e.g., a concentration) of each of the one or more emission gases. In some embodiments, process emissions engine 152 can update one or more settings of a process recipe based on emissions characterization data obtained based on one or more outputs of the AI model 190, as described herein. In some embodiments, predictive system 110 can train AI model 190 to predict the emissions characterization data, as described below and with respect to FIG. 3.

In some embodiments, predictive system 110 includes server machine 170 and server machine 180. Server machine 170 includes a training set generator 172 that is capable of generating training data sets (e.g., a set of data inputs and a set of target outputs) to train, validate, and/or test a machine learning model 190. Some operations of training set generator 172 are described in detail below with respect to FIG. 3. In some embodiments, the training set generator 172 can partition the training data into a training set, a validating set, and a testing set. In some embodiments, the predictive system 110 generates multiple sets of training data.

Server machine 180 includes a training engine 182, a validation engine 184, a selection engine 186, and/or a testing engine 188. An engine can refer to hardware (e.g., circuitry, dedicated logic, programmable logic, microcode, processing device, etc.), software (such as instructions run on a processing device, a general purpose computer system, or a dedicated machine), firmware, microcode, or a combination thereof. Training engine 182 can be capable of training a machine learning model 190. The machine learning model 190 can refer to the model artifact that is created by the training engine 182 using the training data that includes training inputs and corresponding target outputs (correct answers for respective training inputs). The training engine 182 can find patterns in the training data that map the training input to the target output (the answer to be predicted), and provide the machine learning model 190 that captures these patterns. In some embodiments, the machine learning model 190 uses one or more of support vector machine (SVM), Radial Basis Function (RBF), clustering, supervised machine learning, semi-supervised machine learning, unsupervised machine learning, k-nearest neighbor algorithm (k-NN), linear regression, random forest, neural network (e.g., artificial neural network, a recurrent neural network, a convolutional neural network, etc.), clustering techniques (e.g., hierarchical clustering techniques), association techniques (e.g., apriori techniques), classification techniques (e.g., decision trees, random forest techniques, etc.), a variational recurrent auto-encoder, etc. It should be noted that although some embodiments of the present disclosure describe model 190 as a machine learning model, such embodiments can be applied to any type of AI model, non-AI based model (e.g., a statistical model, a physical model, etc.), and/or a hybrid model (e.g., implementing AI techniques and non-AI techniques).

The validation engine 184 can be capable of validating a trained machine learning model 190 using a corresponding set of features of a validation set from training set generator 172. The validation engine 184 can determine an accuracy of each of the trained machine learning models 190 based on the corresponding sets of features of the validation set. The validation engine 184 can discard a trained machine learning model 190 that has an accuracy that does not meet a threshold accuracy. In some embodiments, the selection engine 185 can be capable of selecting a trained machine learning model 190 that has an accuracy that meets a threshold accuracy. In some embodiments, the selection engine 185 can be capable of selecting the trained machine learning model 190 that has the highest accuracy of the trained machine learning models 190.

The testing engine 186 can be capable of testing a trained machine learning model 190 using a corresponding set of features of a testing set from data set generator 172. For example, a first trained machine learning model 190 that was trained using a first set of features of the training set can be tested using the first set of features of the testing set. The testing engine 186 can determine a trained machine learning model 190 that has the highest accuracy of all of the trained machine learning models based on the testing sets.

Predictive server 112 includes a predictive component 114 that is capable of providing data as an input to a trained model 190 and obtaining one or more outputs of the trained model 190. As described herein, predictive component 114 can be a component of or otherwise associated with process emissions engine 152 and can provide process recipe data of a process (e.g., a substrate process, an abatement process, etc.) as an input to trained model 190. Predictive component 114 can obtain one or more outputs of trained model 190, which can include emissions characterization data associated with one or more operations of the process, as described herein.

The client device 120, manufacturing equipment 124, metrology equipment 128, predictive server 112, data store 140, server machine 170, and server machine 180 can be coupled to each other via a network 130. In some embodiments, network 130 is a public network that provides client device 120 with access to predictive server 112, data store 140, and other publicly available computing devices. In some embodiments, network 130 is a private network that provides client device 120 access to manufacturing equipment 124, metrology equipment 128, data store 140, and other privately available computing devices. Network 130 can include one or more wide area networks (WANs), local area networks (LANs), wired networks (e.g., Ethernet network), wireless networks (e.g., an 802.11 network or a Wi-Fi network), cellular networks (e.g., a Long-Term Evolution (LTE) network), routers, hubs, switches, server computers, cloud computing networks, and/or a combination thereof.

It should be noted that in some other implementations, the functions of server machines 170 and 180, as well as predictive server 112, can be provided by a fewer number of machines. For example, in some embodiments, server machines 170 and 180 can be integrated into a single machine, while in some other or similar embodiments, server machines 170 and 180, as well as predictive server 112, can be integrated into a single machine.

In general, functions described in one implementation as being performed by server machine 170, server machine 180, and/or predictive server 112 can also be performed on client device 120. In addition, the functionality attributed to a particular component can be performed by different or multiple components operating together.

In embodiments, a “user” can be represented as a single individual. However, other embodiments of the disclosure encompass a “user” being an entity controlled by a plurality of users and/or an automated source. For example, a set of individual users federated as a group of administrators can be considered a “user.”

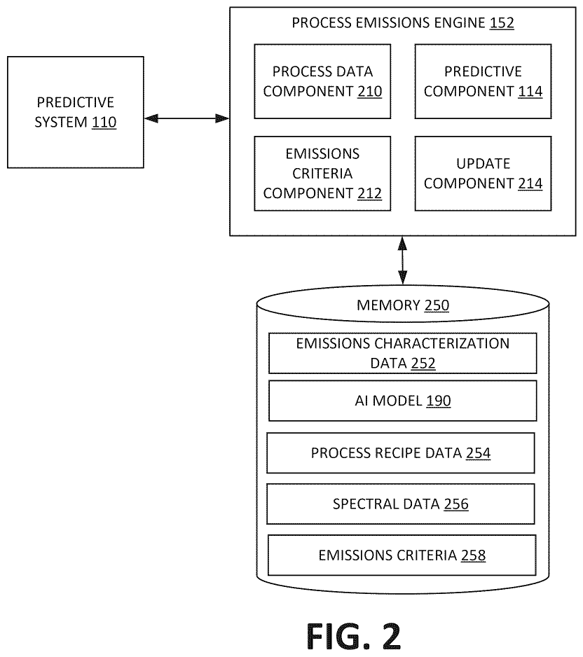

FIG. 2 is a block diagram of an example process emissions engine 152, according to aspects of the present disclosure. As described above, process emissions engine 152 can obtain emissions characterizations data 252 associated with emissions of a process chamber 125 and/or an abatement system 126 of manufacturing equipment 124. In some embodiments, process emissions engine 152 can tune and/or modify settings of a process recipe based on emissions characterizations data 252 for a process. As illustrated by FIG. 2, process emissions engine 152 can include a process data component 210, a predictive component 114, an emissions criteria component 212, and/or an update component 214. In some embodiments, process emissions engine 152 can be connected to predictive system 110 and/or memory 250 (e.g., via network 130). Memory 250 can include one or more portions of data store 140, in some embodiments. In other or similar embodiments, memory 250 can include any memory of or accessible to a component of system 100.

As described herein, process emissions engine 152 can determine emissions characterization data 252 for a substrate process based on one or more outputs of a model 190. AI model 190 may be trained to predict emissions characterization data 252 for a process based on given process recipe data 254 for the process. Details regarding training the emissions characterization data 252 are provided herein with respect to FIG. 3.

FIG. 3 is block diagram depicting an example method 300 for training an AI model, according to aspects of the present disclosure. Method 300 is performed by processing logic that can include hardware (circuitry, dedicated logic, etc.), software (such as is run on a general-purpose computer system or a dedicated machine), firmware, or some combination thereof. In one implementation, method 300 can be performed by a computer system, such as computer system architecture 100 of FIG. 1. In other or similar implementations, one or more operations of method 300 can be performed by one or more other machines not depicted in the figures. In some aspects, one or more operations of method 300 can be performed by training set generator 172.

For simplicity of explanation, method 300 is depicted and described as a series of acts. However, acts in accordance with this disclosure can occur in various orders and/or concurrently, and with other acts not presented and described herein. Furthermore, not all illustrated acts can be performed to implement the methods in accordance with the disclosed subject matter. In addition, those skilled in the art will understand and appreciate that the methods could alternatively be represented as a series of interrelated states via a state diagram or events. Additionally, it should be appreciated that the methods disclosed in this specification are capable of being stored on an article of manufacture to facilitate transporting and transferring such methods to computing devices. The term article of manufacture, as used herein, is intended to encompass a computer program accessible from any computer-readable device or storage media.

At block 310, processing logic initializes a training set T to an empty set (e.g., {}). At block 312, processing logic identifies a process recipe associated with one or more operations of a historical process performed using one or more manufacturing equipment. In some embodiments, the historical process can include a historical substrate process (e.g., a historical etch process, a historical deposition process, a historical polishing process, a historical lithographic process, a historical cleaning process, etc.) performed using process chamber 125 and/or another process chamber (e.g., of system 100 or of another system). In such embodiments, the process recipe can include the process recipe for the historical substrate process. In other or similar embodiments, the historical process can include a historical abatement process performed using abatement system 126 and/or another abatement system (e.g., of system 100 or of another system). In such embodiments, the process recipe can include the process recipe for the historical abatement process. In yet other or similar embodiments, the historical process can include a historical abatement process performed using abatement system 126 subsequent to a historical substrate process performed using process chamber 125. In such embodiments, the process recipe can include the process recipe for the historical substrate process and the historical abatement process. In some embodiments, training set generator 172 can identify or otherwise obtain the process recipe from process recipe data 254 of memory 250. In some embodiments, the process recipe can indicate one or more materials or chemicals that are fed into the manufacturing equipment 124 before, during, or after the historical abatement process and/or one or more settings associated with an environment of the manufacturing equipment 124 before, during or after the historical abatement process.

At block 314, processing logic identifies historical emissions characterization data associated with the one or more operations of the historical process. Historical emissions characterization data can include an indication of one or more emissions gases produced based on one or more operations of the historical process and/or an indication of an amount (e.g., a concentration) of each of the one or more emissions gases. Historical emissions characterization can be determined data based on historical spectral data collected at an outlet of manufacturing equipment 124 (e.g., process chamber 125 and/or abatement system 126) performing the historical process. In some embodiments, an emissions measurement tool can be installed or otherwise included at an outlet of manufacturing equipment 124. At least a portion of emissions of the manufacturing equipment 124 can be flowed or otherwise provided into the emissions measurement tool. The emissions measurement tool can generate spectral data 256 for the portion of the emissions based on data collected by one or more measurement components of the emissions measurement tool. The one or more measurement components of the emissions measurement tool can include, for example, infrared (IR) sensors, Fourier Transform Infrared (FTIR) spectroscopy components, electrochemical sensors, laser-based detectors, particulate sensors, quadrupole mass spectrometry (QMS) components, and so forth.

As emissions are flowed from the outlet of the manufacturing equipment 124 to the emission measurement tool (e.g., during and/or after the historical process), the emission measurement tool can generate spectral data 256 representing spectral features of one or more gases of the emissions during and/or after the historical process. A spectral feature of a gas can include an intensity of a wavelength of photons (e.g., light) detected by the measurement component for the gas. In some embodiments, the spectral data 256 generated by the emission measurement tool can be time series data representing the spectral features of the one or more emission gases over the duration of the historical process. In some embodiments, the emission measurement tool include one or more processing devices that can perform one or more spectra analysis operations to determine emissions characterization data associated with the emission gases. In some embodiments, the emission measurement tool can detect spectral features of one or more gases of the emissions and can associate each spectral feature with one or more reference spectral features associated with a particular gas. The reference spectral features can be provided by a developer or operator of system 100 and/or obtained from a public or private data store (e.g., accessible via network 130). Upon determining that a detected spectral feature correspond to a reference spectral feature associated with a particular gas, the emission measurement tool can determine that the particular gas is present in the emissions. In some embodiments, the emission measurement tool can determine an amount of the particular gas in the emission stream based on the intensity of the wavelength of the detected photons, as indicated by the spectral feature.

Upon determining the emissions characterization data associated with one or more emission gases of the emissions, the emission measurement tool can provide the emissions characterization data to process emissions engine 152 (e.g., via network 130). In some embodiments, the emissions characterization data can indicate the detected emission gases and/or an amount of the detected emission gases for one or more time periods of the historical process. Emissions characterization data can store the emissions characterization data as historical emissions characterization data at memory 250 (e.g., with emissions characterization data 252). In yet other or similar embodiments, the emission measurement tool can provide the spectral data 256 collected for emissions gases of the emissions to process emission engine 152 (or another component of system 100) and/or can store the spectral data 256 at memory 250. Process emission engine 152 and/or the other component of system 100 can determine the emissions characterization data 252 for each emission gas of the emissions during the historical process as described above. In some embodiments, training set generator 172 can obtain the historical emissions characterization data based on the emissions characterization data 252 stored at memory 250 and/or spectral data 256, as described above.

In some embodiments, the emissions characterization data 252 can indicate or otherwise represent a detected emission gas and/or an amount of the detected emission gas for one or more time periods of the historical process, as described above. In additional or alternative embodiments, the emissions characterization data 252 can include time series data representing characteristics of the emissions that are flowed from the outlet of the manufacturing equipment 124. The time series data can include spectral data that, as described above, is indicative of a presence of a particular emission gas and/or an amount of the particular emission gas during a time period at which the emissions gas is flowed out of the manufacturing equipment 124. The time series data can be continuously collected or can be collected at certain intervals (e.g., every second, every few seconds, etc.). The interval at which time series data is collected can be defined or otherwise determined based on a data collection protocol associated with system 100, in some embodiments.

At block 316, processing logic generates a training input based on the identified process recipe. In some embodiments, the training input can include settings of one or more operations of the identified process recipe. The settings can include, but are not limited to, a chemical or material introduced into manufacturing equipment 124 during the historical process, a duration that the chemical or material was introduced into manufacturing equipment 124, a concentration or amount of the chemical or material introduced into the manufacturing equipment 124, a temperature setting of the manufacturing equipment 124, a pressure setting of the manufacturing equipment 124, and so forth. In some embodiments, training set generator 172 can generate a mapping between a particular time period of the historical process and values of one or more settings of the process recipe during the particular time period. In some embodiments, the training input can additionally or alternatively include the generated mapping.

In some embodiments, the training input can additionally or alternatively include sensor data that is collected by or otherwise obtained based on one or more sensors of manufacturing equipment 124 before, during, or after the historical process. In an illustrative example, one or more sensors (e.g., temperature sensors, pressure sensors, flow rate sensors, etc.) may collect data associated with a process at manufacturing equipment 124. The data may be time series data that is collected before, during, or after a process. In some embodiments, the data may be collected at certain intervals (e.g., every second, every few seconds, etc.), as described above. Processing logic can retrieve the collected data (e.g., from memory 250) and can include the collected data with the training input, as described above.

At block 318, processing logic generates a target output based on the identified historical emissions characterization data. In some embodiments, the target output can include the indication of the one or more emissions gases and/or an indication of the amount (e.g., concentration) of one or more emissions gases, as included with emissions characterization data 252 for the historical process and/or determined based on spectral data 256 collected for the historical process. In some embodiments, training set generator 172 can generate a mapping between a particular time period during which the spectral data 256 associated with the emissions characterization data 252 was collected and additionally or alternatively include the generated mapping with the target output. In some instances, there can be a time delay between a time period when one or more settings of the process recipe were applied during the historical process and a time period when the spectral data 256 for the emissions corresponding to the settings of the process recipe were collected. This may be caused by a distance (e.g., spatial distance, temporal distance, etc.) between the emissions leaving the manufacturing equipment 124 and the collection and/or analysis of spectral data 256 by the emissions measurement tool. In some embodiments, training set generator 172 can identify historical emissions characterization data that corresponds to the process recipe settings associated with the training input in view of the delay for inclusion in the target output. In some embodiments, the delay can be approximated or otherwise determined based on experimental or test data associated with manufacturing equipment 124.

In some additional or alternative embodiments, training set generator 172 can determine one or more settings of the process recipe for the historical process that have a higher degree of impact on the emissions characterization data 252 than other settings of the process recipe and include an indication of the one or more settings with the target output. In some embodiments, training set generator 172 can provide the one or more settings of the process recipe and the emissions characterization data 252 as an input to an additional AI model trained to predict process recipe settings that have the higher degree of impact based on given emissions characterization data. Training set generator 172 can determine the one or more settings of the process recipe having he higher degree of impact based on one or more outputs of the additional AI model. In other or similar embodiments, training set generator 172 can determine the one or more settings based on one or more outputs of a physics model for the historical substrate process. In yet other or similar embodiments, training set generator 172 can determine the one or more settings based on a notification provided by an operator or developer of system 100 (e.g., via a user interface of client device 120).

At block 320, processing logic generates a mapping between the training input and the target output. At block 322, processing logic adds the mapping to the training set T. At block 324, processing logic determines whether the training set T includes a sufficient amount of training data to train a machine learning model. It should be noted that in some implementations, the sufficiency of training set T can be determined based simply on the number of mappings in the training set, while in some other implementations, the sufficiency of training set T can be determined based on one or more other criteria (e.g., a measure of diversity of the training examples, etc.) in addition to, or instead of, the number of input/output mappings. Responsive to determining the training set does not include a sufficient amount of training data to train the machine learning model, method 300 returns to block 312. Responsive to determining the training set, T, includes a sufficient amount of training data to train the machine learning model, method 300 continues to block 326.

At block 326, processing logic provides training set T to train the machine learning model. In one implementation, the training set T is provided to training engine 182 of server machine 180 to perform the training. In the case of a neural network, for example, input values of a given input/output mapping are input to the neural network, and output values of the input/output mapping are stored in the output nodes of the neural network. The connection weights in the neural network are then adjusted in accordance with a learning algorithm (e.g., backpropagation, etc.), and the procedure is repeated for the other input/output mappings in the training set T. After block 326, machine learning model 190 can be used to predict emissions characterization data of a current substrate process and/or a future substrate process performed using manufacturing equipment 124, as described herein.

Referring back to FIG. 2, process emissions engine 152 can determine emissions characterization data 252 for a current process performed using manufacturing equipment 124 and/or a future process to be performed using manufacturing equipment 124 based on one or more outputs of model 190 and, based on the determined emissions characterization data 252, modify or update one or more settings of the process recipe for the current process (e.g., if one or more emissions criteria 258 are not satisfied). Embodiments relating to determining the emissions characterization data 252 for the process and modifying or updating the one or more settings of the process recipe are described with respect to FIGS. 2, 4, and 5.

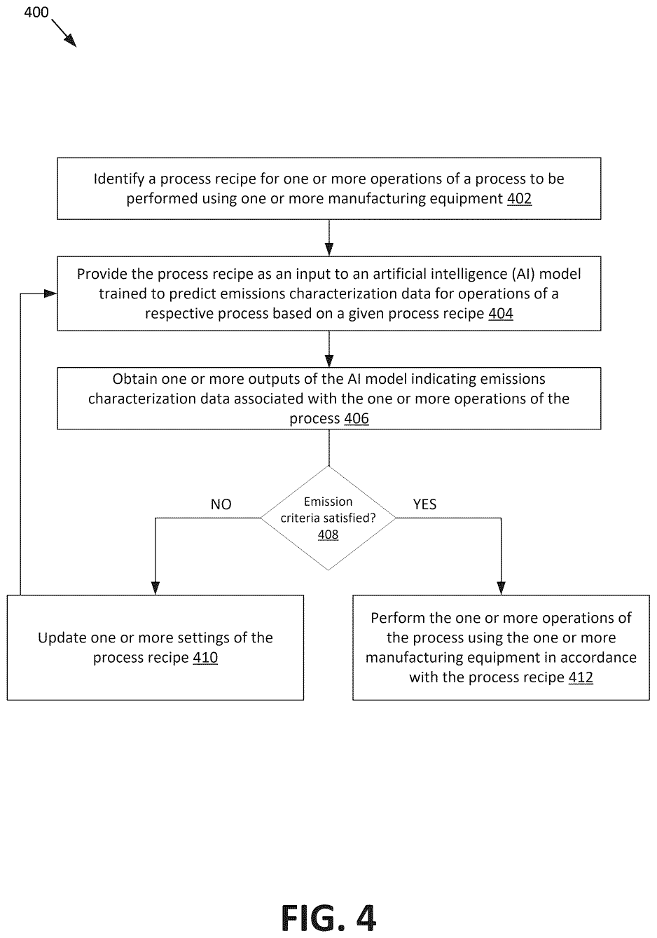

FIG. 4 is a flow chart of an example method 400 for predicting a substrate process emissions chemistry, according to aspects of the present disclosure. Method 400 is performed by processing logic that can include hardware (circuitry, dedicated logic, etc.), software (such as is run on a general-purpose computer system or a dedicated machine), firmware, or some combination thereof. In one implementation, method 400 can be performed by a computer system, such as computer system architecture 100 of FIG. 1. In other or similar implementations, one or more operations of method 400 can be performed by one or more other machines not depicted in the figures. In some aspects, one or more operations of method 300 can be performed by process emissions engine 152 and/or predictive component 114.

For simplicity of explanation, method 400 is depicted and described as a series of acts. However, acts in accordance with this disclosure can occur in various orders and/or concurrently, and with other acts not presented and described herein. Furthermore, not all illustrated acts can be performed to implement the methods in accordance with the disclosed subject matter. In addition, those skilled in the art will understand and appreciate that the methods could alternatively be represented as a series of interrelated states via a state diagram or events. Additionally, it should be appreciated that the methods disclosed in this specification are capable of being stored on an article of manufacture to facilitate transporting and transferring such methods to computing devices. The term article of manufacture, as used herein, is intended to encompass a computer program accessible from any computer-readable device or storage media.

At block 402, processing logic identifies a process recipe for one or more operations of a process to be performed using one or more manufacturing equipment. In some embodiments, process data component 210 of process emissions engine 152 can identify the process recipe. Process data component 210 can determine a process that is currently performed or is to be performed using manufacturing equipment 124 and can identify the process recipe for such process at memory 250, in some embodiments. In some embodiments, process data component 210 can determine the process that is currently performed or is to be performed based on a notification or signal received from a system controller of the manufacturing system and/or a notification received from a client device 120 associated with a user of system 100 (e.g., an engineer, an operator). In other or similar embodiments, process data component 210 can identify a process schedule associated with the manufacturing equipment 124 and determine such process based on the identified process schedule.

In some embodiments, process data component 210 can receive a notification of multiple process recipes that are being evaluated (e.g., by an engineer, an operator, etc.) for application during a process performed using manufacturing equipment 124. Process data component 210 can identify each of the multiple process recipes to be provided as input to the AI model (e.g., simultaneously, consecutively, etc.), in such embodiments.

At block 404, processing logic provides the process recipe as an input to an AI model trained to predict emissions characterization data for operations of a respective process based on a given process recipe. Predictive component 114 can provide the process recipe as the input to AI model 190. AI model 190 can be trained to predict the emissions characterization data for the respective process based on the given process recipe, as described herein. At block 406, processing logic obtains one or more outputs of the AI model indicating emissions characterization data associated with one or more operations of the process. The one or more outputs can indicate emissions characterization data 252 associated with the one or more operations of the process. As described herein, the emissions characterization data 252 can include an indication of one or more emissions gases produced based on the one or more operations of the process in accordance with the process recipe and/or an indication of an amount (e.g., a concentration) of each of the one or more emissions gases. As described above, in some embodiments, predictive component 114 can provide multiple process recipes as an input to AI model 190. In such embodiments, predictive component 114 can determine the emissions characterization data 252 for each of the multiple process recipe based on the output(s) of the AI model 190.

At block 408, processing logic determines whether the emissions characterization data associated with the one or more operations satisfies one or more emissions criteria. In some embodiments, emissions criteria component 212 can identify one or more emissions criteria 258 associated with manufacturing equipment 124 and/or the process to be performed using manufacturing equipment 124. Emissions criteria component 212 can receive a notification of emissions criteria 258 from a client device 120 associated with a user of system 100, in some embodiments. In other or similar embodiments, emissions criteria component 212 may identify emissions criteria 258 from a public data store or a private data store that includes emissions criteria for one or more processes (e.g., substrate processes, abatement processes, etc.) and/or one or more types of manufacturing equipment. In an illustrative example, emissions criteria component 212 may identify emissions criteria 258 from a public data store that stores emissions criteria defined by an emissions authority (e.g., an industry authority, a governmental authority, etc.).

In some embodiments, emissions criteria component 212 can determine whether the emissions characterization data 252 satisfies the emissions criteria 258 by determining whether the emissions gases indicated by the emissions characterization data 252 include a restricted emissions gas, as indicated by the emissions criteria 258. A restricted emissions gas can include a gas that is recognized as dangerous (e.g., toxic) or otherwise has a severe negative impact on an environment or people exposed to the gas. In other or similar embodiments, emissions criteria component 212 can determine whether the emissions characterization data 252 satisfies the emissions criteria 258 by determining whether the amount (e.g., concentration) of the one or more emissions gases falls below a threshold amount, as defined by the emissions criteria 258. In some embodiments emissions criteria component 212 can determine that the emissions criteria 258 are satisfied upon determining that the one or emissions gases indicated by the emissions characterization data 252 does not include a restricted gas and/or determining that the amount of the one or more emissions gases falls below the threshold amount.

Upon a determination that the one or more emissions criteria are not satisfied, method 400 proceeds to block 410. At block 410, processing logic updates one or more settings of the process recipe. As indicated above, in some embodiments, AI model 190 can be further trained to predict one or more settings of a given process recipe that have a higher degree of impact on emissions characterization data 252 than other settings of the process recipe. In such embodiments, update component 214 may identify one or more settings of the process recipe for modification based on the indicated one or more settings by the output(s) of AI model 190. In some embodiments, update component 214 can determine updated values for the identified one or more settings by providing the one or more settings and/or the emissions characterization data 252 as an input to a tuning engine (not shown). The tuning engine can perform one or more tuning operations to identify values of the one or more settings that, when applied to the process, will achieve a target outcome. In some embodiments, the target outcome can correspond to mitigating or removing the one or more emissions gases from the emissions of the process. In some embodiments, the tuning operations of the tuning engine can include a mean squared error (MSE) function, a mean absolute error (MAE) function, a Huber loss function, an R-Squared (R²) function, and so forth. Update component 214 can update the settings of the process recipe by modifying the values for the settings to match the values identified based on the one or more operations of the tuning engine.

Upon updating the one or more settings of the process recipe, method 400 returns to block 404, where processing logic (e.g., predictive component 114) provides the updated settings of the process recipe as an input to the AI model 190. Predictive component 114 can obtain one or more outputs of the AI model 190, which can indicate updated emissions characterization data 252 based on the updated settings of the process recipe. Emissions criteria component 212 may determine whether the updated emissions characterization data 252 satisfies the emissions criteria 258, as described above.

Referring back to block 408, upon a determination that the one or more emissions criteria are satisfied, method 400 proceeds to block 412. At block 412, processing logic performs the one or more operations of the process using the one or more manufacturing equipment in accordance with the process recipe. In some embodiments, process emissions engine 152 can provide the process recipe (or the updated process recipe) to a system controller of the manufacturing system and an instruction to initiate the process using the process chamber 125 and/or the abatement system 126.

In some embodiments, process emissions engine 152 may not update settings of a process recipe having emissions characteristic data 252 that is determined not to satisfy the emissions criteria 258. In such embodiments, process emissions engine 152 may instead provide a notification to the client device 120 associated with the user of system 100 that the process recipe does not satisfy the emissions criteria 258. The client device 120 can provide the notification for presentation to the user (e.g., via a UI of the client device 120). The user of the system 100 can provide a notification (e.g., via the UI of client device 120) of whether to initiate performance of the process recipe and/or an additional process recipe (e.g., that does satisfy the emissions criteria 258). In an illustrative example, process emissions engine 152 may provide the client device 120 with the emissions characterization data 252 for each of the multiple process recipes that are being evaluated for a process to be performed using manufacturing equipment 124. Client device 120 may present the emissions characterization data 252 for each of the multiple process recipes for presentation to the user via a UI and may receive a notification of a selection of a particular process recipe by the user via the UI. Upon receiving the notification of the user selection, client device 120 can transmit the notification to process emissions engine 152 and/or a system controller for the manufacturing system. In some embodiments, the system controller can initiate a process using manufacturing equipment 124 in accordance with the process recipe associated with the user selection.

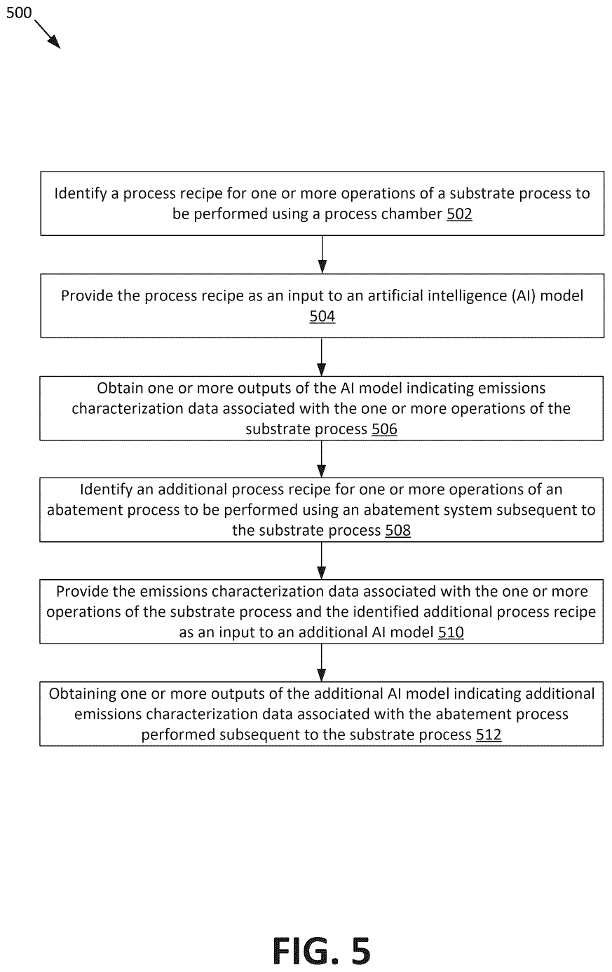

FIG. 5 is a flow chart of another example method 500 for predicting a substrate process emissions chemistry, according to aspects of the present disclosure. Method 500 is performed by processing logic that can include hardware (circuitry, dedicated logic, etc.), software (such as is run on a general-purpose computer system or a dedicated machine), firmware, or some combination thereof. In one implementation, method 400 can be performed by a computer system, such as computer system architecture 100 of FIG. 1. In other or similar implementations, one or more operations of method 400 can be performed by one or more other machines not depicted in the figures. In some aspects, one or more operations of method 300 can be performed by process emissions engine 152 and/or predictive component 114.

For simplicity of explanation, method 500 is depicted and described as a series of acts. However, acts in accordance with this disclosure can occur in various orders and/or concurrently, and with other acts not presented and described herein. Furthermore, not all illustrated acts can be performed to implement the methods in accordance with the disclosed subject matter. In addition, those skilled in the art will understand and appreciate that the methods could alternatively be represented as a series of interrelated states via a state diagram or events. Additionally, it should be appreciated that the methods disclosed in this specification are capable of being stored on an article of manufacture to facilitate transporting and transferring such methods to computing devices. The term article of manufacture, as used herein, is intended to encompass a computer program accessible from any computer-readable device or storage media.

At block 502, processing logic identifies a process recipe for one or more operations of a substrate process to be performed using a process chamber. Process data component 210 can identify the process recipe based on process recipe data 254 (e.g., at memory 250), as described above. In some embodiments, the substrate process is to be performed using process chamber 125. At block 504, processing logic provides the process recipe as an input to an AI model. The AI model can include AI model 190, which, as described above, is trained to predict emissions characterization data for operations of a respective process based on a given process recipe. Predictive component 114 can provide the process recipe as an input to AI model 190, as described above. In some embodiments, the AI model of block 504 may be trained to predict emissions characterization data for operations of a respective substrate process (e.g., and not for operations of a respective abatement process), in accordance with embodiments described herein. At block 506, processing logic can obtain one or more outputs of the AI model, where the one or more outputs indicate emissions characterization data associated with the one or more operations of the substrate process. Predictive component 114 can obtain one or more outputs of the AI model, as described above.

At block 508, processing logic can identify additional process recipe data for one or more operations of an abatement process to be performed using an abatement system subsequent to the substrate process. Process data component 210 can identify the additional process recipe based process recipe data 254 (e.g., at memory 250), as described above. In some embodiments, the abatement process is to be performed using abatement system 126 after performance of the substrate process using process chamber 125. At block 510, processing logic provides the emissions characterization data associated with the one or more operations of the substrate process and the identified additional process recipe as an input to the additional AI model. Predictive component 114 can provide the emissions characterization data and/or the additional process recipe data as an input to the additional model, as described herein. The additional AI model can include AI model 190 and/or another AI model that is trained to predict emissions characterization data associated with the one or more operations of a respective abatement process (e.g., and not for operations of a respective substrate process). In some embodiments, the emissions characterization data provided as an input to the additional AI model can be obtained based on the one or more outputs of the AI model described with respect to block 506. Such emissions characterization data can be treated or otherwise considered by the additional AI model as a respective setting of the abatement process (e.g., an indication of one or more chemicals or materials flowed into the abatement system 126, an indication of an amount of the one or more chemicals or materials), in some embodiments.

At block 512, processing logic obtains one or more outputs of the additional AI model indicating additional emissions characterization data associated with the abatement process performed subsequent to the substrate process. In some embodiments, the additional emissions characterization data 252 of the one or more outputs of the additional AI model can indicate the total emissions that may be released by system 100 (e.g., prior to modification of the settings for the substrate process recipe and/or the abatement process recipe). Update component 214 may update one or more settings of the substrate process recipe and/or the abatement process recipe (e.g., based on a determination by emissions criteria component 212 of whether the additional emissions characterization data 252 satisfies the emissions criteria 258), as described above.

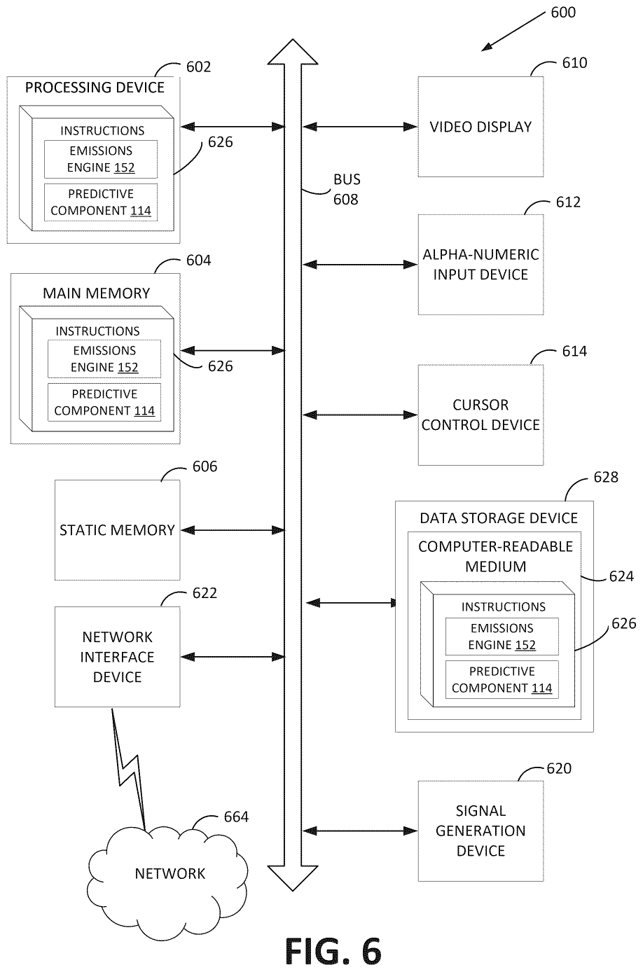

FIG. 6 depicts a block diagram of an illustrative computer system 600 operating in accordance with one or more aspects of the present disclosure. In alternative embodiments, the machine can be connected (e.g., networked) to other machines in a Local Area Network (LAN), an intranet, an extranet, or the Internet. The machine can operate in the capacity of a server or a client machine in a client-server network environment, or as a peer machine in a peer-to-peer (or distributed) network environment. The machine can be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In embodiments, computing device 600 can correspond to predictive server 112 of FIG. 1 or another processing device of system 100. In other or similar embodiments, computing device 600 can correspond to computing system 150 of system 100.

The example computing device 600 includes a processing device 602, a main memory 604 (e.g., read-only memory (ROM), flash memory, dynamic random access memory (DRAM) such as synchronous DRAM (SDRAM), etc.), a static memory 606 (e.g., flash memory, static random access memory (SRAM), etc.), and a secondary memory (e.g., a data storage device 628), which communicate with each other via a bus 608.

Processing device 602 can represent one or more general-purpose processors such as a microprocessor, central processing unit, or the like. More particularly, the processing device 602 can be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. Processing device 602 can also be or include a system on a chip (SoC), programmable logic controller (PLC), or other type of processing device. Processing device 602 is configured to execute the processing logic for performing operations and steps discussed herein.

The computing device 600 can further include a network interface device 622 for communicating with a network 664. The computing device 600 also can include a video display unit 610 (e.g., a liquid crystal display (LCD) or a cathode ray tube (CRT)), an alphanumeric input device 612 (e.g., a keyboard), a cursor control device 614 (e.g., a mouse), and a signal generation device 620 (e.g., a speaker).

The data storage device 628 can include a machine-readable storage medium (or more specifically a non-transitory computer-readable storage medium) 624 on which is stored one or more sets of instructions 626 embodying any one or more of the methodologies or functions described herein. Wherein a non-transitory storage medium refers to a storage medium other than a carrier wave. The instructions 626 can also reside, completely or at least partially, within the main memory 604 and/or within the processing device 602 during execution thereof by the computer device 600, the main memory 604 and the processing device 602 also constituting computer-readable storage media.

The computer-readable storage medium 624 can also be used to store model 190 and data used to train model 190. The computer readable storage medium 624 can also store a software library containing methods that call model 190. While the computer-readable storage medium 624 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies of the present disclosure. The term “computer-readable storage medium” shall accordingly be taken to include, but not be limited to, solid-state memories, and optical and magnetic media.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure can be practiced without these specific details. In other instances, well-known components or methods are not described in detail or are presented in simple block diagram format in order to avoid unnecessarily obscuring the present disclosure. Thus, the specific details set forth are merely exemplary. Particular implementations can vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method can be altered so that certain operations can be performed in an inverse order so that certain operations can be performed, at least in part, concurrently with other operations. In another embodiment, instructions or sub-operations of distinct operations can be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method comprising:
identifying a process recipe for one or more operations of a process to be performed using one or more manufacturing equipment;
providing the process recipe as an input to an artificial intelligence (AI) model trained to predict emissions characterization data for operations of a respective process based on a given process recipe;
obtaining one or more outputs of the AI model indicating emissions characterization data associated with the one or more operations of the process, wherein the emissions characterization data comprises one or more of:
an indication of one or more emission gases produced based on the one or more operations of the process in accordance with the process recipe, or
an indication of an amount of each of the one or more emission gases;
determining whether the emissions characterization data associated with the one or more operations satisfies one or more emission criteria; and
responsive to determining that the emissions characterization data associated with the one or more operations satisfies the one or more emission criteria, performing the one or more operations of the process using the one or more manufacturing equipment in accordance with the process recipe.

2. The method of claim 1, further comprising:
responsive to determining that the emissions characterization data for the one or more operations of the process does not satisfy the one or more emission criteria, updating one or more settings of the process recipe; and
performing the one or more operations of the process using the one or more manufacturing equipment in accordance with the updated one or more settings of the process recipe.

3. The method of claim 2, further comprising;
providing the updated one or more settings of the process recipe as an additional input to the AI model;
obtaining one or more additional outputs of the AI model comprising updated emissions characterization data for the process, wherein the updated emissions characterization data comprises one or more of:
an indication of the one or more emission gases produced by the process performed in accordance with the updated one or more settings of the process recipe, or
an indication of an updated amount of the one or more emission gases,
wherein the process is performed using the one or more manufacturing equipment in accordance with the updated one or more settings of the process recipe responsive to a determination that the updated emissions characterization data for the process satisfies the one or more emission criteria.

4. The method of claim 2, wherein the AI model is further trained to predict one or more settings of the respective process recipe that have a higher degree of impact on the predicted emissions characterization data than other settings of the respective process recipe, and wherein updating the one or more settings of the process recipe comprises:
determining, based on the one or more outputs of the AI model, the one or more settings of the process recipe that have the higher degree of impact on the emissions characterization data associated with the process; and
determining updated values for each of determined one or more settings.

5. The method of claim 1, wherein the one or more manufacturing equipment comprises at least one of:
a processing chamber that performs the process, or
an abatement system that performs one or more abatement operations on one or more gases of an outlet of the processing chamber.

6. The method of claim 1, wherein determining whether the emissions characterization data associated with the process satisfies the one or more emission criteria comprises at least one of:
determining whether the indicated one or more emission gases comprise a restricted emission gas, or
determining whether an amount of the one or more emission gases falls below a threshold amount.

7. The method of claim 1, wherein the process comprises at least one of an etching process, a deposition process, a polishing process, a lithographic process or a cleaning process.

8. The method of claim 1, further comprising:
transmitting the emissions characterization data associated with the one or more operations of the process to a client device for presentation to a user via a user interface of the client device.

9. The method of claim 1, wherein the process recipe is for one or more operations of a substrate process to be performed using a process chamber, and wherein the method further comprises:
identifying an additional process recipe of an abatement process to be performed using an abatement system subsequent to performance of one or more operations of the process using the process chamber;
providing the identified additional process recipe and the emissions characterization data associated with the one or more operations of the process as an input to an additional AI model trained to predict emissions characterization data for operations of a respective abatement process following a respective substrate;
obtaining one or more outputs of the additional AI model comprises additional emissions characterization data associated with the abatement process performed subsequent to the one or more operations of the process using the process chamber,
wherein the one or more operations of the process are performed in accordance with the process recipe responsive to a further determination that the additional emissions characterization data satisfies the one or more emissions criteria.

10. A system comprising:
a memory; and
a set of one or more processing devices coupled to the memory, wherein the set of one or more processing devices is to:
generate training data for training a machine learning model to predict emissions characterization data for a respective process recipe, wherein to generate the training data, the set of one or more processing devices is to:
generate a training input comprising a process recipe associated with one or more operations of a historical process performed using one or more manufacturing equipment; and
generate a target output for the training input, wherein the target output comprises historical emissions characterization data collected for the one or more operations of the historical process, wherein the historical emissions characterization data comprises one or more of an indication of one or more emissions gases produced based on the one or more operations of the historical process in accordance with the process recipe, or an indication of an amount of each of the one or more emission gases; and
provide the training data to train the machine learning model on (i) a set of training inputs comprising the training input and (ii) a set of target outputs comprising the target output.

11. The system of claim 10, wherein the set of one or more processing devices is further to:
identify historical spectral data associated with the one or more emissions gases produced based on the one or more operations of the historical process; and
determining, based on the historical spectral data, one or more of a composition of the one or more emissions gases and a concentration of the one or more emissions gases.

12. The system of claim 11, wherein the set of one or more processing devices is to perform at least one of:
determining the one or more emissions gases produced based on the one or more operations of the historical process based on the determined composition of the one or more emissions gases, or
determining the amount of each of the one or more emissions gases based on the determined concentration of the one or more emissions gases.

13. The system of claim 10, wherein the one or more manufacturing equipment comprises at least one of:
a processing chamber that performs the historical process, or
an abatement system that performs one or more historical abatement operations on one or more gases of an outlet of the processing chamber.

14. The system of claim 10, wherein the historical process comprises at least one of a historical etching process, a historical deposition process, a historical polishing process, a historical lithographic process, a historical cleaning process, or a historical abatement process.

15. The system of claim 10, wherein the target output for the training input further comprises an indication of one or more settings of the process recipe that have a higher degree of impact on the historical emissions characterization data than other settings of the process recipe.

16. A non-transitory computer readable medium comprising instructions that, when executed by a set of one or more processing devices, cause the set of one or more processing devices to:
identify a process recipe for one or more operations of a process to be performed using one or more manufacturing equipment;
provide the process recipe as an input to an artificial intelligence (AI) model trained to predict emissions characterization data for operations of a respective process based on a given process recipe;
obtain one or more outputs of the AI model indicating emissions characterization data associated with the one or more operations of the process, wherein the emissions characterization data comprises one or more of:
an indication of one or more emission gases produced based on the one or more operations of the process in accordance with the process recipe, or
an indication of an amount of each of the one or more emission gases;
determine whether the emissions characterization data associated with the one or more operations satisfies one or more emission criteria; and
responsive to determining that the emissions characterization data associated with the one or more operations satisfies the one or more emission criteria, perform the one or more operations of the process using the one or more manufacturing equipment in accordance with the process recipe.

17. The non-transitory computer readable medium of claim 16, wherein the set of one or more processing devices is further to:
responsive to determining that the emissions characterization data for the one or more operations of the process does not satisfy the one or more emission criteria, update one or more settings of the process recipe; and
perform the one or more operations of the process using the one or more manufacturing equipment in accordance with the updated one or more settings of the process recipe.

18. The non-transitory computer readable medium of claim 17, wherein the set of one or more processing devices is further to:
provide the updated one or more settings of the process recipe as an additional input to the AI model;
obtain one or more additional outputs of the AI model comprising updated emissions characterization data for the process, wherein the updated emissions characterization data comprises one or more of:
an indication of the one or more emission gases produced by the process performed in accordance with the updated one or more settings of the process recipe, or
an indication of an updated amount of the one or more emission gases,
wherein the process is performed using the one or more manufacturing equipment in accordance with the updated one or more settings of the process recipe responsive to a determination that the updated emissions characterization data for the process satisfies the one or more emission criteria.

19. The non-transitory computer readable medium of claim 17, wherein the AI model is further trained to predict one or more settings of the respective process recipe that have a higher degree of impact on the predicted emissions characterization data than other settings of the respective process recipe, and wherein to update the one or more settings of the process recipe, the set of one or more processing devices is further to:
determine, based on the one or more outputs of the AI model, the one or more settings of the process recipe that have the higher degree of impact on the emissions characterization data associated with the process; and
determine updated values for each of determined one or more settings.

20. The non-transitory computer readable medium of claim 16, wherein the one or more manufacturing equipment comprises at least one of:
a processing chamber that performs the process, or
an abatement system that performs one or more abatement operations on one or more gases of an outlet of the processing chamber.
